(19) United States
(12) Patent Application Publication
(10) Pub. No.: US 2018/0246643 A1
(43) Pub. Date: Aug. 30, 2018

(54) System and Method to Perform Runtime Saves on Dual Data Rate NVDIMMs

(71) Applicant: DELL PRODUCTS, LP, Round Rock, TX (US)

(72) Inventors: John E. Jenne, Austin, TX (US); Vadhiraj Sankaranarayanan, Austin, TX (US); Andrew Butcher, Cedar Park, TX (US)

(21) Appl. No.: 15/445,236

(22) Filed: Feb. 28, 2017

(51) Int. Cl. G06F 3/06; G11C 11/4096; G11C 11/4093

(52) U.S. Cl. CPC G06F 3/061; G11C 11/4096; G06F 3/0625; G06F 3/0679; G06F 3/0659; G11C 11/4093

(57) ABSTRACT

A DIMM includes a DRAM device and a non-volatile memory device. The DIMM is configured in a first mode to receive a save signal from a memory controller via a save pin of the DIMM and to perform a first save operation to transfer data from the DRAM device to the non-volatile memory device in response to receiving the save signal. The DIMM is further configured in a second mode to receive a save command from the memory controller via a command bus of the DIMM and to perform a second save operation to transfer the data from the DRAM device to the non-volatile memory device in response to receiving the save command.

### FIELD OF THE DISCLOSURE

This disclosure generally relates to information handling systems, and more particularly relates to performing runtime saves on dual data rate NVDIMMs.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

Memory for an information handling system often includes one or more Dual In-Line Memory Modules (DIMMs). The DIMMs are typically configured in accordance with a particular Double Data Rate (DDR) standard, such as a fourth generation standard (DDR4). A non-volatile DIMM (NVDIMM) of a particular type (the NVDIMM-N) may operate as a normal DIMM, but also includes sufficient non-volatile (flash) memory to store the contents of the DIMM in the event of a power failure. As such, an information handling system that supports NVDIMM-N operation may include a separate power source dedicated to operating the NVDIMM-N in a save operation.

### SUMMARY

A DIMM may include a DRAM device and a non-volatile memory device. The DIMM may be configured in a first mode to receive a save signal from a memory controller via a save pin of the DIMM and to perform a first save operation to transfer data from the DRAM device to the non-volatile memory device in response to receiving the save signal. The DIMM may be further configured in a second mode to receive a save command from the memory controller via a command bus of the DIMM and to perform a second save operation to transfer the data from the DRAM device to the non-volatile memory device in response to receiving the save command.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram illustrating an information handling system that includes an NVDIMM according to an embodiment of the present disclosure;

FIG. 2 is a flowchart illustrating a method for providing a runtime save command to an NVDIMM according to an embodiment of the present disclosure; and

FIG. 3 is a block diagram illustrating a generalized information handling system according to an embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

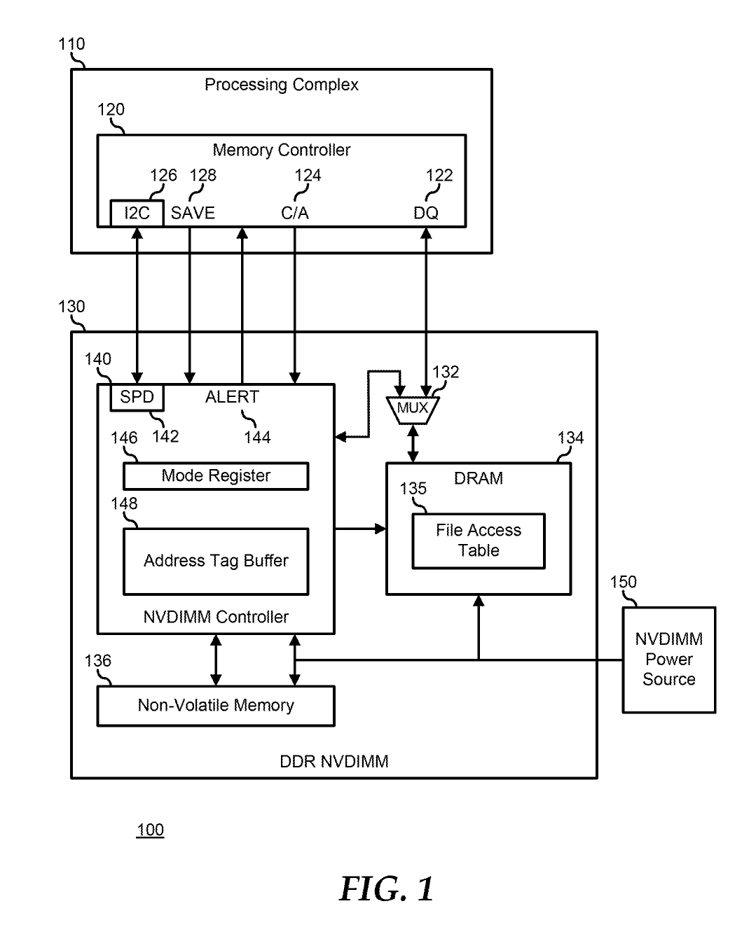

FIG. 1 illustrates an embodiment of an information handling system 100. For purpose of this disclosure information handling system 100 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 100 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 100 can include processing resources for executing machine-executable code, such as a central processing unit (CPU), a programmable logic array (PLA), an embedded device such as a System-on-a-Chip (SoC), or other control logic hardware. Information handling system 100 can also include one or more computer-readable medium for storing machine-executable code, such as software or data. Additional components of information handling system 100 can include one or more storage devices that can store machine-executable code, one or more communications ports for communicating with external devices, and various input and output (I/O) devices, such as a keyboard, a mouse, and a video display. Information handling system can 100 also include one or more buses operable to transmit information between the various hardware components.

A problem may arise when information handling system 100 employs JEDEC Standard NVDIMM-N type NVDIMMs. A save data operation is typically performed in response to a power anomaly, or another such event where data from Dynamic Random Access Memory devices (DRAMs) of the NVDIMM is saved to a non-volatile memory device of the NVDIMM. However, mechanisms for performing a save data operation during runtime are limited to performing transactions on an Inter-Integrated Circuit (I2C) interface.

Information handling system 100 includes a processing complex 110, a Dual Data Rate (DDR) Non-Volatile Dual In-Line Memory Module (NVDIMM) 130, and an NVDIMM power source 150. NVDIMM 130 represents an NVDIMM-N type NVDIMM that includes memory mapped Dynamic Random Access Memory (DRAM) devices of the NVDIMM that provide the for data storage under normal operating conditions for information handling system 100. Under certain operating conditions, such as in the event of a loss of system power, the data stored in the DRAM devices is saved to non-volatile memory devices of NVDIMM 130. Later, such as when the system power is restored, the data stored in the non-volatile memory devices is restored to the DRAM devices.

Typically, a save data operation is initiated when a memory controller of processing complex 110 asserts a particular save data signal to NVDIMM 130. The memory controller can assert the save data signal in response to, for example, an AC power loss scenario. Here, when the memory controller is informed of the AC power loss scenario, the memory controller can store various data, such as data from processor caches and data buffers, to the DRAM devices of NVDIMM 130, place the DRAM devices into a self-refresh mode, and then assert the save data signal to the NVDIMM. At this time, the components of NVDIMM 130 are supplied with power from NVDIMM power source 150 for the duration of the save data operation. In response to the assertion of the save data signal, an NVDIMM controller reads the data from the DRAM devices, stores the data to one or more non-volatile memory devices of the NVDIMM, and turns the NVDIMM off until a subsequent power cycle event turns the NVDIMM back on. When NVDIMM 130 is turned off in response to the save data operation, the memory controller cannot determine from the NVDIMM whether or not the save data operations was successful, that is, whether or not the data from the DRAM devices was successfully saved to the non-volatile memory devices. Instead, the system BIOS must wait for the subsequent power on sequence on information handling system 100, and the system BIOS instructs the memory controller to read status registers of the NVDIMM controller via an Inter-Integrated Circuit (I2C) interface to determine if the save data operation was successful. In a particular embodiment, the save data operation represents a JEDEC Standard SAVE operation, and the save data signal represents a JEDEC Standard SAVE_n signal, such as may be provided by a memory controller to a NVDIMM.

NVDIMM power source 150 is configured to provide power to one or more NVDIMMs similar to NVDIMM 130 for the projected duration of the save data operation. However, as the number of DIMM slots on information handling system 100 increases, the use of NVDIMM-N technology increases, or as the density of NVDIMM-N devices increases, the amount and duration of the power provided by NVDIMM power source 150 must similarly increase. As such, the amount of real estate on a printed circuit board that instantiates information handling system 100 that must be dedicated to NVDIMM power source 150 increases, as does the cost of the components to implement the NVDIMM-N technology.

The memory controller of processing complex 110 is further configured to implement a I2C save data operation. In a particular embodiment, the memory controller initiates a I2C save data operation by placing the DRAM devices in the self-refresh mode to isolate the DRAM devices from the memory controller and by writing to a register of the NVDIMM controller of NVDIMM 130 via the I2C interface to initiate the I2C save data operation. Here, the components of NVDIMM 130 are supplied with power not from NVDIMM power source 150, but from a system level power supply of information handling system 100 that supplies power for the components of the NVDIMM during normal operation. In response to the initiation of the I2C save data operation, the NVDIMM controller reads the data from the DRAM devices, stores the data to one or more non-volatile memory devices of the NVDIMM, and stores status information related to the success or failure of the I2C save data operation in the I2C register of the NVDIMM controller. Here, the memory controller polls the register of the NVDIMM controller via the I2C interface to determine when the I2C save data operation is complete. When the I2C save data operation is complete, the memory controller queries the register of the NVDIMM controller via the I2C interface to determine whether or not the I2C save data operation was completed successfully. If the I2C save data operation was completed successfully, then the memory controller wakes up the DRAM devices, and normal operation resumes. If the I2C save data operations was not completed successfully, then the memory controller can retry the I2C save data operation by writing to the register of the NVDIMM controller to execute a new I2C save data operation.

In another embodiment, when the memory controller wants to initiate a runtime save data operation on NVDIMM 130, the memory controller issues a runtime save data command on a command and address bus to the NVDIMM, without asserting the save data signal to the NVDIMM and without writing to the register of the NVDIMM controller via the I2C interface. Then, in response to the runtime save data command, the NVDIMM controller executes a runtime save data operation as described above. In a particular embodiment, when the NVDIMM controller is done executing the runtime save data operation, the NVDIMM controller provides an alert signal back to the memory controller to indicate that the runtime save data operation is completed. In a particular embodiment, the alert signal represents the JEDEC Standard ALERT_n signal. In a particular case where the alert signal represents the JEDEC Standard ALERT_n signal, the length of time for which the ALERT_n signal is asserted can be correlated to provide an indication as to the success or failure of the runtime save data operation.

In another embodiment, the memory controller can be configured to provide a pre-determined amount of time for the NVDIMM controller to complete the runtime save data operation. Then, in response either to the receipt of the alert signal or to the lapse of the pre-determined amount of time, the memory controller provides command information on the command and address bus to suspend the self-refresh mode for the DRAM devices, and normal operation resumes.

Here, the memory controller can determine whether or not the runtime save data operation was successfully completed in one of two ways. In a first embodiment, when the NVDIMM controller completes the runtime save data operation, the NVDIMM controller stores status information related to the success or failure of the runtime save data operation in the I2C register of the NVDIMM controller. Then, when the runtime save data operation is complete, the memory controller queries the register of the NVDIMM controller via the I2C interface to determine whether or not the runtime save data operation was completed successfully. In another embodiment, when the NVDIMM controller completes the runtime save data operation, the NVDIMM controller stores status information related to the success or failure of the runtime save data operation to a particular location on the DRAM devices of NVDIMM 130, such as a Mode Register Set register of a DDR5 DRAM device. Then, when the runtime save data operation is complete, the memory controller issues a command on the command and address bus to read the status information from the DRAM devices.

In a particular embodiment, when the memory controller of processing complex 110 issues a runtime save data command on the command and address bus the NVDIMM 130, the runtime save data command includes parameters for specifying one or more memory ranges of the DRAM devices of the NVDIMM that are to be saved. Here, when the NVDIMM controller of NVDIMM 130 receives the memory ranges, the NVDIMM controller operates to save only the data from the DRAM devices that is associated with the memory ranges to the non-volatile memory device of the NVDIMM.

Processing complex 110 includes a hardware memory controller 120 and a file access table 114. Processing complex 110 represents the hardware, software, firmware, and other elements associated with the performance of the processing tasks associated with information handling system. As such, processing complex 110 may be understood to include one or more data processors or processing cores, one or more input/output (I/O) devices such as processor, memory, or I/O controller hub, system memory including random access memory (RAM) and system read-only memory (ROM), mass data storage devices, video processors, network interface devices, or other devices typical to an information handling system, as needed or desired. Memory controller 120 represents a device of processing complex 110 that manages the flow of data going to and from NVDIMM 130, As such, memory controller 120 is connected to NVDIMM 130 via a double-data rate (DDR) channel. The DDR channel includes a data bus (DQ), a control/address bus (C/A) 124, an Inter-Integrated Circuit (I2C) interface 126, a save data signal output 128, and an input for receiving an alert signal from NVDIMM 130.

NVDIMM 130 includes a memory channel multiplexor 132, a DDR DRAM device 134, non-volatile memory devices 126, and an NVDIMM controller 230. DRAM device 134 include a file access table 135 similar to file access table 112. NVDIMM controller 140 includes a serial presence detect (SPD) logic 142 connected to I2C interface 126, an input for receiving save data signal output 128, an alert output 144 to memory controller 120, inputs for receiving C/A 124, one or more mode registers 146, and an address tag buffer 148. NVDIMM controller 140 is connected to C/A 124 to receive command and address information from memory controller 120 for DRAM device 134. NVDIMM controller 140 is also connected to DRAM device 134 to provide the command and address information to the DRAM device. DRAM device 134 is connected to multiplexor 132 to selectively connect to data bus DQ 122 to transfer data between the DRAM device and memory controller 120, and to NVDIMM controller 140 to transfer data between the DRAM device and non-volatile memory device 136. Note that the skilled artisan will recognize that multiplexor 132 and DRAM device 134 are typically representative of multiple multiplexors and DRAM devices in the typical NVDIMM.

In normal operation, memory controller 130 issues memory transactions for memory locations associated with DRAM device 134 by providing command and address information on C/A 124 to NVDIMM controller 140. For example, a memory read to a memory location associated with DRAM device 134 will start with memory controller 120 presenting data read command and address information on C/A 124. NVDIMM controller 140 will provide the read data command and address information to DRAM device 134 and set multiplexor 132 to permit data transfers between memory controller 120 and the DRAM device, and the DRAM device will provide the read data from the addressed memory location to memory controller 120 on DQ 122. In another example, a memory write to a memory location associated with DRAM device 134 will start with memory controller 120 presenting write data command and address information on C/A 124 and presenting the write data on DQ 122. NVDIMM controller 140 will provide the write data command and address information to DRAM device 134 and set multiplexor 132 to permit data transfers between memory controller 120 and the DRAM device, and the DRAM device will write the data to the addressed memory location.

Information handling system 100 operates to provide for a save data operation to be performed for the data stored on NVDIMM 130. Here, an event, such as a loss of system power, can trigger the save data operation. The save data operation can include steps by processing complex 110, such as the flushing of all processor caches to NVDIMM 130, initiating an Asynchronous DRAM Refresh (ADR) mode on NVDIMM 130 to isolate DRAM device 134 from memory controller 112, and asserting a save data signal on save data signal output 128. NVDIMM 130 then proceeds to save data the date from DRAM device 134 to non-volatile memory device 136. In the ADR mode, multiplexor 132 is set to connect DRAM device 134 to NVDIMM controller 140. In this way, DRAM device 134 is isolated from memory controller 120. NVDIMM controller 140 then reads the data from DRAM device 134, and stores the data to non-volatile memory device 136. During the save data operation, NVDIMM 130 receives power from NVDIMM power source 150 to perform the data reads from DRAM device 134, and to store the data to non-volatile memory device 136. In a particular embodiment, NVDIMM power source 150 represents a battery device that is dedicated to NVDIMM 130 and any other NVDIMM devices of information handling system 100, as needed or desired, in order to conduct the runtime save data operation on the information handling system. In another embodiment, NVDIMM power source 150 represents one or more super-capacitors that are configured to provide power to NVDIMM 130 and any other NVDIMM devices of information handling system 100, as needed or desired, in order to conduct the runtime save data operation on the information handling system. Information handling system 100 also operates to provide for I2C save data operations to be performed for the data stored on NVDIMM 130. In the I2C save data operation, memory controller 120 initiates the runtime save data operation by writing to a register of SPD logic 142 via I2C interface 126 to initiate the runtime save data operation, as described above.

In another embodiment, information handling system 100 operates to provide runtime save data operations. Here, when memory controller 120 wants to initiate a runtime save data operation on NVDIMM 130, the memory controller issues a runtime save data command on C/A 124, without asserting the save data signal on save data signal output 128, and without writing to the register of SPD logic 142 via I2C interface 126. Here, the command and address information includes a runtime save data command, in response to which NVDIMM 130 proceeds to save data the date from DRAM device 134 to non-volatile memory device 136. In a particular embodiment, NVDIMM 130 operates similarly in the runtime save data operation as in the ADR mode, as described above. In particular, NVDIMM controller 140 sets DRAM device 134 into self-refresh mode, and multiplexor 132 is set to connect the DRAM device to the NVDIMM controller to isolate the DRAM device from memory controller 120. NVDIMM controller 140 then reads the data from DRAM device 134, and stores the data to non-volatile memory device 136. In the runtime save data operation, there may be no need for NVDIMM 130 to receive power from NVDIMM power source 150 to perform the data reads from DRAM device 134, or to store the data to non-volatile memory device 136.

The runtime save data operation can be initiated by processing complex 110 under a variety of circumstances. For example, the runtime save data operation can be initiated by a platform BIOS or UEFI, or by an operating system of processing complex 110 in order to provide a checkpoint for a particular process or program. Then, if an unexpected software event causes processing complex 110 to crash, a checkpoint of system operation can be retrieved from NVDIMM 130 via a memory restore data operation. In another example, processing complex 110 or NVDIMM 130 can detect an increase in the rate of failures in memory reads or memory writes on the NVDIMM, or other indications that the reliability of operation of the NVDIMM is at risk. In a particular case, processing complex 110 can detect a problem, and can direct memory controller 120 to initiate a runtime save data operation by issuing a runtime save data command on C/A 124 to NVDIMM controller 130. In another case, NVDIMM controller 130 can detect a problem and can assert alert signal 144. In response, processing complex 110 can direct memory controller 120 to initiate a runtime save data operation by issuing a runtime save data command on C/A 124 to NVDIMM controller 130. In a particular embodiment, when memory controller 120 issues a runtime save data command on C/A 123, the runtime save data command includes parameters for specifying one or more memory ranges of DRAM device 134 that are to be saved. Here, when NVDIMM controller 140 receives the memory ranges, and the NVDIMM controller operates to save only the data from DRAM device 134 that is associated with the memory ranges to non-volatile memory device 136.

In a particular embodiment, memory controller 120 waits a predetermined amount of time to permit NVDIMM 130 to complete the runtime save data operation, before processing complex 110 resumes normal operations on NVDIMM 130. In another embodiment, NVDIMM controller 140 asserts alert signal 144 when the runtime save data operation is completed, and processing complex 110 does not resume normal operations on NVDIMM 130 until memory controller 120 receives the alert signal. In a particular embodiment, upon successful completion of the runtime save data operation, NVDIMM controller 130 sets a particular bit in a Mode Register Set (MRS) register of DRAM device 134. Then, memory controller 120 can read the MRS register to determine if the runtime save data operation was successful. In another embodiment, the runtime save data command includes information that defines a memory range within the addressable memory range of NVDIMM 130 that is to be stored to non-volatile memory device 126. In this way, the runtime save data operation can be used, for example to debut an application or process, by saving data in memory address ranges that are associated with the application or process.

Note that, as illustrated, DRAM device 134 is isolated from memory controller 120 by selecting to connect the DRAM devices to NVDIMM controller 140 via multiplexor 132, but this is not necessarily so. In another embodiment, DRAM devices similar to DRAM devices 134 represent dual-port devices. Here, an NVDIMM similar to NVDIMM 130 does not include a multiplexor similar to multiplexor 132. Instead, for each DRAM device, a first port of the DRAM device is directly connected to a memory controller similar to memory controller 120, and a second port of the DRAM device is directly connected to an NVDIMM controller similar to NVDIMM controller 140. Here, when the DRAM devices are to be isolated from the memory controller, the NVDIMM is configured such that the DRAM device ignores activity on its first port, thereby effectively isolating the DRAM device from the memory controller. Other memory configurations may be utilized in providing DRAM devices and non-volatile memory devices, as needed or desired. In particular, although non-volatile memory device 136 is shown as a single device, this is not necessarily so, and an individual non-volatile memory device can be provided for each bank of DRAM devices.

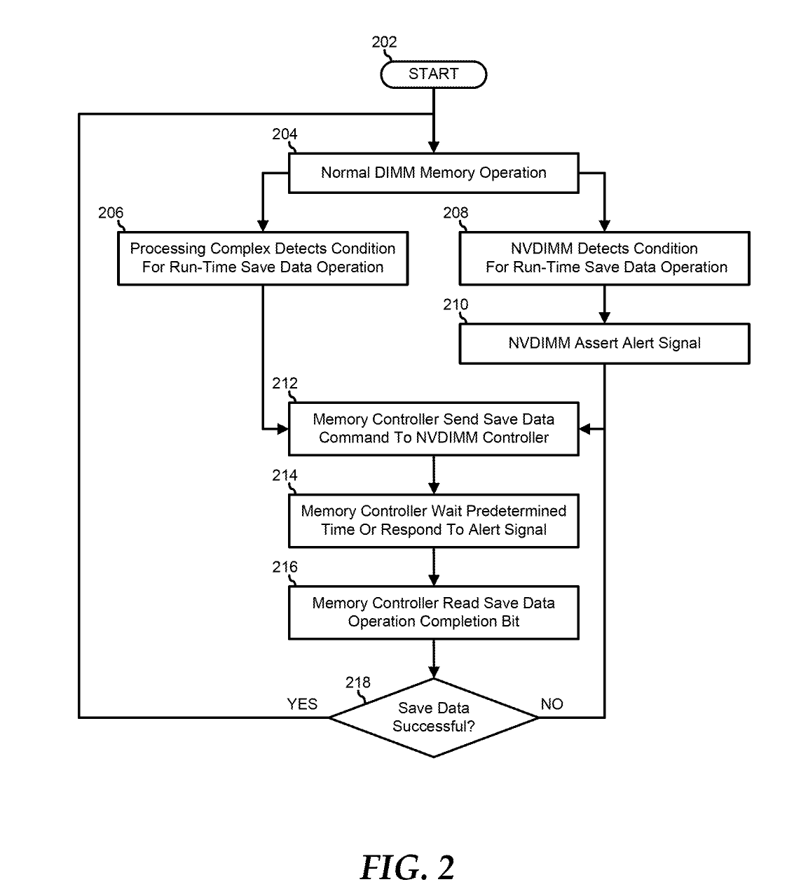

FIG. 2 illustrates a method for providing a runtime save data command to an NVDIMM, starting at block 202. An information handling system operates an NVDIMM in normal DIMM memory operation in block 204. For example, information handling system 100 can operate to read and write date to NVDIMM 130, utilizing the NVDIMM in normal DIMM operations. In a first case, the method proceeds to block 206, where a processing complex of the information handling system detects a condition for which a runtime save data operation is indicated and the method proceeds to block 212, as described below. For example, processing complex 110 can determine that a checkpoint is needed, or that the performance of memory reads from NVDIMM 130 is degrading. In another case, the method proceeds from block 204 to block 208, where an NVDIMM of the information handling system detects a condition for which a runtime save data operation is indicated in block 208, the NVDIMM asserts an alert signal to the memory controller in block 210, and the method proceeds to block 212, as described below. For example, NVDIMM 130 can determine that the performance of memory writes from memory controller 120 is degrading.

In block 212, the memory controller sends a runtime save data command to the NVDIMM in response to either the processing complex detecting a condition for which the runtime save data operation is indicated in block 206, or in response to the assertion of the alert signal by the NVDIMM in block 210. The method proceeds to block 214 where the memory controller waits for a predetermined time, or for the assertion of the alert signal by the NVDIMM to indicate that the NVDIMM has completed the runtime save data operation. Here, it is understood that the NVDIMM performs the runtime save data operation in response to the runtime save data command. When the predetermined time has elapsed or the memory controller detects the assertion of the alert signal, the memory controller reads a save data operation completion bit from an MRS register of a DRAM of the NVDIMM to determine if the runtime save data operation was successful in block 216. A decision is made as to whether or not the runtime save data operation was successful in decision block 218. If so, the “YES” branch of decision block 218 is taken and the method returns to block 204 where the information handling system operates the NVDIMM in normal DIMM memory operation. If the runtime save data operation was not successful, the “NO” branch of decision block 218 is taken and the method returns to block 212 where the memory controller sends a runtime save data command to the NVDIMM.

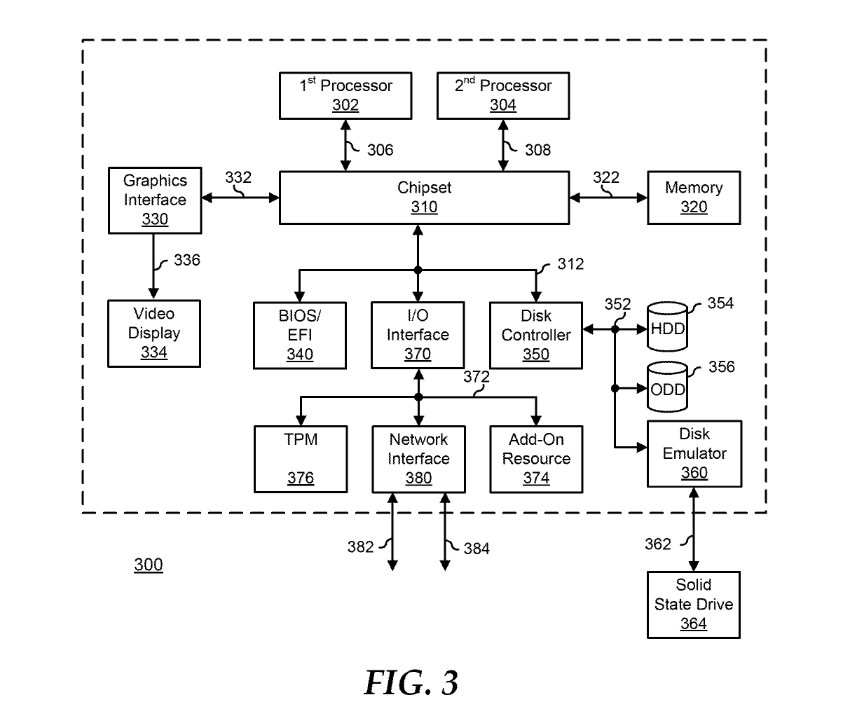

FIG. 3 illustrates a generalized embodiment of information handling system 300. For purpose of this disclosure information handling system 300 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 300 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 300 can include processing resources for executing machine-executable code, such as a central processing unit (CPU), a programmable logic array (PLA), an embedded device such as a System-on-a-Chip (SoC), or other control logic hardware. Information handling system 300 can also include one or more computer-readable medium for storing machine-executable code, such as software or data. Additional components of information handling system 300 can include one or more storage devices that can store machine-executable code, one or more communications ports for communicating with external devices, and various input and output (I/O) devices, such as a keyboard, a mouse, and a video display. Information handling system 300 can also include one or more buses operable to transmit information between the various hardware components.

Information handling system 300 can include devices or modules that embody one or more of the devices or modules described above, and operates to perform one or more of the methods described above. Information handling system 300 includes a processors 302 and 304, a chipset 310, a memory 320, a graphics interface 330, include a basic input and output system/extensible firmware interface (BIOS/EFI) module 340, a disk controller 350, a disk emulator 360, an input/output (I/O) interface 370, and a network interface 380. Processor 302 is connected to chipset 310 via processor interface 306, and processor 304 is connected to the chipset via processor interface 308. Memory 320 is connected to chipset 310 via a memory bus 322. Graphics interface 330 is connected to chipset 310 via a graphics interface 332, and provides a video display output 336 to a video display 334. In a particular embodiment, information handling system 300 includes separate memories that are dedicated to each of processors 302 and 304 via separate memory interfaces. An example of memory 320 includes random access memory (RAM) such as static RAM (SRAM), dynamic RAM (DRAM), non-volatile RAM (NV-RAM), or the like, read only memory (ROM), another type of memory, or a combination thereof.

BIOS/EFI module 340, disk controller 350, and I/O interface 370 are connected to chipset 310 via an I/O channel 312. An example of I/O channel 312 includes a Peripheral Component Interconnect (PCI) interface, a PCI-Extended (PCI-X) interface, a high speed PCI-Express (PCIe) interface, another industry standard or proprietary communication interface, or a combination thereof. Chipset 310 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/EFI module 340 includes BIOS/EFI code operable to detect resources within information handling system 300, to provide drivers for the resources, initialize the resources, and access the resources. BIOS/EFI module 340 includes code that operates to detect resources within information handling system 300, to provide drivers for the resources, to initialize the resources, and to access the resources.

Disk controller 350 includes a disk interface 352 that connects the disc controller to a hard disk drive (HDD) 354, to an optical disk drive (ODD) 356, and to disk emulator 360. An example of disk interface 352 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 360 permits a solid-state drive 364 to be connected to information handling system 300 via an external interface 362. An example of external interface 362 includes a USB interface, an IEEE 1394 (Firewire) interface, a proprietary interface, or a combination thereof. Alternatively, solid-state drive 364 can be disposed within information handling system 300.

I/O interface 370 includes a peripheral interface 372 that connects the I/O interface to an add-on resource 374, to a TPM 376, and to network interface 380. Peripheral interface 372 can be the same type of interface as I/O channel 312, or can be a different type of interface. As such, I/O interface 370 extends the capacity of I/O channel 312 when peripheral interface 372 and the I/O channel are of the same type, and the I/O interface translates information from a format suitable to the I/O channel to a format suitable to the peripheral channel 372 when they are of a different type. Add-on resource 374 can include a data storage system, an additional graphics interface, a network interface card (NIC), a sound/video processing card, another add-on resource, or a combination thereof. Add-on resource 374 can be on a main circuit board, on separate circuit board or add-in card disposed within information handling system 300, a device that is external to the information handling system, or a combination thereof.

Network interface 380 represents a NIC disposed within information handling system 300, on a main circuit board of the information handling system, integrated onto another component such as chipset 310, in another suitable location, or a combination thereof. Network interface device 380 includes network channels 382 and 384 that provide interfaces to devices that are external to information handling system 300. In a particular embodiment, network channels 382 and 384 are of a different type than peripheral channel 372 and network interface 380 translates information from a format suitable to the peripheral channel to a format suitable to external devices. An example of network channels 382 and 384 includes InfiniBand channels, Fibre Channel channels, Gigabit Ethernet channels, proprietary channel architectures, or a combination thereof. Network channels 382 and 384 can be connected to external network resources (not illustrated). The network resource can include another information handling system, a data storage system, another network, a grid management system, another suitable resource, or a combination thereof.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An Dual In-Line Memory Module (DIMM), comprising:
a Dynamic Random Access Memory (DRAM) device; and
a non-volatile memory device;
wherein the DIMM is configured in a first mode to:
receive a save signal from a memory controller via a save pin of the DIMM; and
perform a first save operation to transfer data from the DRAM device to the non-volatile memory device in response to receiving the save signal; and
wherein the DIMM is configured in a second mode to:
receive a save command from the memory controller via a command bus of the DIMM; and
perform a second save operation to transfer the data from the DRAM device to the non-volatile memory device in response to receiving the save command.

2. The DIMM of claim 1, wherein the DIMM is further configured:
in the first mode to receive power for the first save operation from a first power source; and
in the second mode to receive power for the second save operation from a second power source.

3. The DIMM of claim 1, wherein, in performing the first and the second save operations, the DIMM is further configured to isolate the DRAM device from the memory controller.

4. The DIMM of claim 3, further comprising:
a multiplexor coupled to the DRAM device and configured to selectably couple the DRAM device to the memory controller and to the non-volatile memory device.

5. The DIMM of claim 4, wherein, in isolating the DRAM device from the memory controller, the DIMM is further configured to select the multiplexor to couple the DRAM device to the non-volatile memory device

6. The DIMM of claim 1, wherein the DRAM device has a first capacity and the non-volatile memory device has a second storage capacity, the second storage capacity being greater than the first storage capacity.

7. The DIMM of claim 6, wherein the DIMM comprises an N-type non-volatile DIMM (NVDIMM-N).

8. The DIMM of claim 1, wherein the DIMM comprises a fifth generation Double Data Rate (DDR5) DIMM.

9. A method, comprising:
receiving, by a Dual In-Line Memory Module (DIMM), a save signal from a memory controller via a save pin of the DIMM;
performing a first save operation to transfer data from a Dynamic Random Access Memory (DRAM) device of the DIMM to a non-volatile memory device of the DIMM in response to receiving the save signal;
receiving, by the DIMM, a save command from the memory controller via a command bus of the DIMM; and
performing a second save operation to transfer the data from the DRAM device to the non-volatile memory device in response to receiving the save command.

10. The method of claim 9, further comprising:
receiving, by the DIMM, power for the first save operation from a first power source; and
receiving, by the DIMM, power for the second save operation from a second power source.

11. The method of claim 10, wherein, in performing the first and the second save operations, the method further comprises:
isolating the DRAM device from the memory controller.

12. The method of claim 11, further comprising:
coupling a multiplexor the DRAM device; and
configuring the multiplexor to selectably couple the DRAM device to the memory controller and to the non-volatile memory device.

13. The method of claim 12, wherein, in isolating the DRAM device from the memory controller, the method further comprises:
selecting the multiplexor to couple the DRAM device to the non-volatile memory device.

14. The method of claim 9, wherein the DRAM device has a first capacity and the non-volatile memory device has a second storage capacity, the second storage capacity being greater than the first storage capacity.

15. The method of claim 14, wherein the DIMM comprises an N-type non-volatile DIMM (NVDIMM-N).

16. The method of claim 9, wherein the DIMM comprises a fifth generation Double Data Rate (DDR5) DIMM.

17. A Dual In-Line Memory Module (DIMM), comprising:
a Dynamic Random Access Memory (DRAM) device including a data bus interface to transfer data between the DRAM device and a memory controller coupled to the data bus;
a non-volatile memory device; and
a DIMM controller including a command bus interface to receive memory commands from the memory controller, and including a save input to receive a save signal from the memory controller, the DIMM controller configured to:
receive the save signal;
provide first control signals to the DRAM device in response to receiving the save signal, the first control signals to direct the DRAM device to perform a first save operation to transfer data to the non-volatile memory device;
receive a command on the command bus interface; and
provide second control signals to the DRAM device, the second control signals to direct the DRAM device to perform a second save operation to transfer the data to the non-volatile memory device.

18. The DIMM of claim 17, wherein the DIMM is further configured:
receive power for the first save operation from a first power source; and
receive power for the second save operation from a second power source.

19. The DIMM of claim 17, wherein the DRAM device has a first capacity and the non-volatile memory device has a second storage capacity, the second storage capacity being greater than the first storage capacity.

20. The DIMM of claim 17, wherein the DIMM comprises a fifth generation Double Data Rate (DDR5) DIMM.
